(19) United States
(12) Patent Application Publication
(10) Pub. No.: US 2017/0170018 A1
(43) Pub. Date: Jun. 15, 2017

(54) CONFORMAL DOPING USING DOPANT GAS ON HYDROGEN PLASMA TREATED SURFACE

(71) Applicant: Lam Research Corporation, Fremont, CA (US)

(72) Inventors: Yunsang Kim, Monte Sereno, CA (US); Youn Gi Hong, Pleasanton, CA (US); Ivan L. Berry, III, San Jose, CA (US)

(21) Appl. No.: 14/967,994

(22) Filed: Dec. 14, 2015

(51) Int. Cl. H01L 21/223; H01L 21/31; H01L 29/36; H01L 21/324

(52) U.S. Cl. CPC H01L 21/2236; H01L 21/3242; H01L 21/31; H01L 29/36

(57) ABSTRACT

Well-controlled, conformal doping of semiconductor substrates may be achieved by low temperature hydrogen-containing plasma treatment prior to gas phase doping. Substrates doped in this manner may be capped and annealed for thermal drive-in of the dopant. The technique is particularly applicable to the formation of ultrashallow junctions (USJs) in three-dimensional (3D) semiconductor structures, such as FinFET and Gate-All-Around (GAA) devices.

### BACKGROUND

This disclosure relates generally to the field of semiconductor processing and devices. In particular, the disclosure relates to gas phase doping of semiconductor substrates, and is particularly, though not solely, applicable to the formation of ultrashallow junctions (USJs) in three-dimensional (3D) semiconductor structures, such as FinFET and Gate-All-Around (GAA) devices.

Three-dimensional (3D) semiconductor structures, such as found in FinFET and Gate-GAA devices, provide considerable fabrication challenges as device sizes continue to decrease. Among these challenges is the reliable formation of high quality USJs as heavily doped source/drain (S/D) contacts of 3D metal-oxide-semiconductor field effect transistors (MOSFETs).

Various prior techniques for forming USJs have been found to be limited in terms of the depth and conformality of doping that can be achieved. For example, ion implantation techniques, such as ion beam or plasma doping, are conventionally used for doping S/D contacts. Ion implantation techniques involve the energetic introduction of dopant species into the semiconductor lattice and thereby induce crystal damage. Defects are generated, such as interstitials and vacancies, which interact with dopants to broaden the junction profile. Such a transient-enhanced diffusion (TED) limits the formation of high quality of USJs.

Monolayer doping (MLD) is another doping technique used for fabricating USJs as source/drain (S/D) contacts of MOSFETs. MLD uses a the self-limiting surface reaction properties of a crystalline semiconductor substrate to deposit self-assembled, covalently bonded dopant-containing monolayers, followed by a subsequent annealing step for the incorporation and diffusion of the deposited dopants. Dopant dose control is achievable by the self-limiting formation of covalently attached dopants deposited on the crystal surface, and MLD dopant atoms are then thermally diffused from the surface into the bulk.

However, the reliable formation of effective USJs less than 10 nm in depth with doping conformality has proved difficult.

### SUMMARY

Gas phase doping of semiconductor substrates as described herein can provide a high degree of control of doping depth, extent and conformality. Conformal doping has been achieved by a relatively gentle hydrogen plasma treatment of a crystalline semiconductor (e.g., low temperature hydrogen-containing plasma exposure of silicon) substrate, followed by exposure of the hydrogen-containing plasma-modified crystal structure of the semiconductor substrate to a dopant gas such that the modified crystal structure of the semiconductor substrate is conformally doped with the dopant. The hydrogen-containing plasma exposure may be integrated with a substrate pre-clean process. The described techniques are particularly, though not solely, beneficially applicable to the formation of USJs in three-dimensional (3D) semiconductor structures, such as FinFET and GAA devices.

Aspects of the present disclosure are directed to methods of fabricating doped semiconductor substrates without ion implantation or dopant deposition, and associate devices and apparatus.

In one implementation, a semiconductor processing method involves exposing a semiconductor substrate to a hydrogen plasma (e.g., a H₂ plasma) to modify a surface region crystal structure of the semiconductor substrate without lattice or other mechanical damage in the semiconductor substrate crystal structure, and exposing the hydrogen plasma-treated substrate surface to a dopant gas such that the modified surface region is doped with the dopant. The doping is conducted without energetic ion-induced implanting of the dopant into the substrate, and there is no deposition of a dopant species on the substrate surface. The dopant may be n-type (e.g., P from PH₃ gas) or p-type (e.g., B from B₂H₆ gas). The gas phase-doped semiconductor may then be capped and anneal to drive-in the dopant. A doped modified surface region of the substrate at a concentration of at least 5E18 atoms/cm³ at a depth of at least 5 nm can be achieved by such thermal annealing. Such a doped region is suitable for and may be adapted to form part of a USJ.

Another implementation is a USJ having a depth of less than 20 nm, or less than 10 nm, or less than 5 nm, the junction having a conformal doped region of the semiconductor substrate with a concentration of at least 5E18 atoms/cm³, for example at least 1E19 atoms/cm³, and up to at least 1E20 atoms/cm³ or more.

Another aspect of the disclosure relates to semiconductor processing apparatus having one or more process chambers, each process chamber comprising a chuck; one or more gas inlets into the process chambers and associated flow-control hardware; a plasma generator associated with one or more chambers; and a controller having at least one processor and a memory. The processor and the memory are communicatively connected with one another, the processor is at least operatively connected with the flow-control hardware, and the memory stores computer-executable instructions for controlling the processor to at least expose a semiconductor substrate to a hydrogen plasma to modify a surface region crystal structure of the semiconductor substrate without lattice or other mechanical damage in the semiconductor substrate crystal structure, and expose the hydrogen plasma-treated substrate surface to a dopant gas such that the modified surface region is doped with the dopant.

These and other features and advantages of the disclosure will be described in more detail below with reference to the associated drawings.

### BRIEF DESCRIPTION OF THE DRAWINGS

FIG. 1. depicts a process flow for gas phase conformal doping of a semiconductor substrate in accordance with an aspect of this disclosure.

FIGS. 2A-B illustrate examples of features and three-dimensional (3D) semiconductor structures to which the present disclosure is particularly applicable, for example for the formation of USJs.

FIGS. 3A-E illustrate a process flow for gas phase conformal doping of a semiconductor substrate in accordance with one embodiment of this disclosure.

FIG. 4 schematically shows a cross-sectional view of an inductively coupled plasma integrated etching and deposition apparatus appropriate for implementing certain embodiments described herein.

FIG. 5A is an electron micrograph image and 5B is a plot demonstrating the doping of a silicon substrate in one example from an experiment conducted to validate the method of this disclosure.

FIG. 6 is a plot demonstrating the doping of a silicon substrate in another example from an experiment conducted to validate the method of this disclosure.

### DETAILED DESCRIPTION

Reference will now be made in detail to specific embodiments of the disclosure. Examples of the specific embodiments are illustrated in the accompanying drawings. While the disclosure will be described in conjunction with these specific embodiments, it will be understood that it is not intended to limit the disclosure to such specific embodiments. On the contrary, it is intended to cover alternatives, modifications, and equivalents as may be included within the spirit and scope of the disclosure. In the following description, numerous specific details are set forth in order to provide a thorough understanding of the present disclosure. The present disclosure may be practiced without some or all of these specific details. In other instances, well known process operations have not been described in detail so as to not unnecessarily obscure the present disclosure.

Introduction

Well-controlled doping of semiconductor substrates may be achieved by low temperature hydrogen plasma treatment prior to gas phase doping. In the description that follows, reference is primarily made to a preferred embodiment of H₂ plasma as the hydrogen plasma. It should be understood that other embodiments, using hydrogen plasmas based on other suitable hydrogen-containing species and mixtures, including possibly C₂H₂, CH₄, a remote plasma that just contains atomic H, combinations of these with each other, H₂ or other gas species, etc., are also contemplated. Moreover, the hydrogen plasma may also commonly contain an inert carrier gas, such as He or Ar. Substrates doped in this manner provide conformal doping at high concentrations at the semiconductor surface, and the doped substrates may be capped and annealed for thermal drive-in of the dopant. The technique is particularly applicable to the formation of USJs in three-dimensional (3D) semiconductor structures, such as FinFET and GAA devices.

While hydrogen plasmas (e.g., H₂ plasmas) are widely used in IC processing, their use is this context is unknown, and unexpectedly appears to greatly increase the amount of dopant (e.g., phosphorus from PH₃ for n-type doping of a silicon substrate) that incorporates on a crystalline semiconductor surface. This in turn leads to a much higher dopant concentration in the near surface after thermal drive-in by annealing.

The doping is conducted without energetic ion-induced implanting of the dopant into the substrate, and there is no deposition of a dopant species on the substrate surface. The low temperature plasma exposure can conducted at a temperature and/or for a time that is insufficient to reduce native oxide on the semiconductor surface. After the initial gas phase doping exposure, the substrate may be capped with a thin dielectric capping layer, typically an oxide or nitride layer, to prevent dopant from desorbing during subsequent processing. After capping, the dopant at the semiconductor surface (semiconductor/cap interface) can be driven-in to the substrate by a thermal annealing treatment.

According to this disclosure, doping depths of from less than 5 nm up to 20 nm may be achieved with thermal annealing, with dopant concentration levels adequate to form transistor junctions. Such a doped region is suitable for and may be adapted to form part of a USJ. Moreover, doping in accordance with this disclosure may be conformal. So the disclosure is particularly applicable to the formation of USJs in three-dimensional (3D) semiconductor structures, such as FinFET and GAA devices.

Process

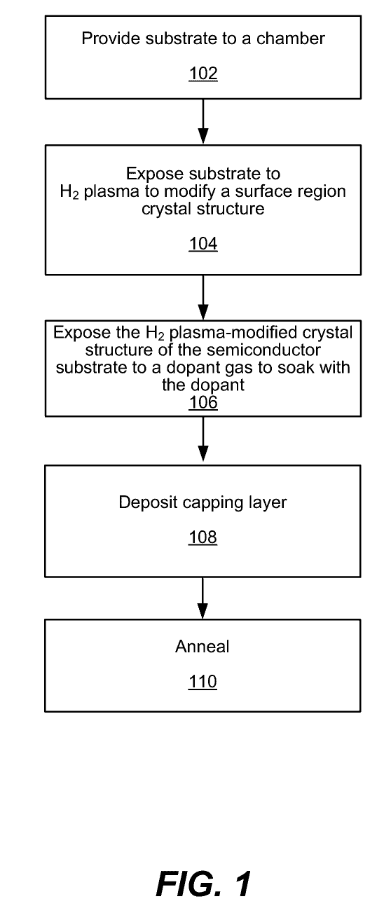

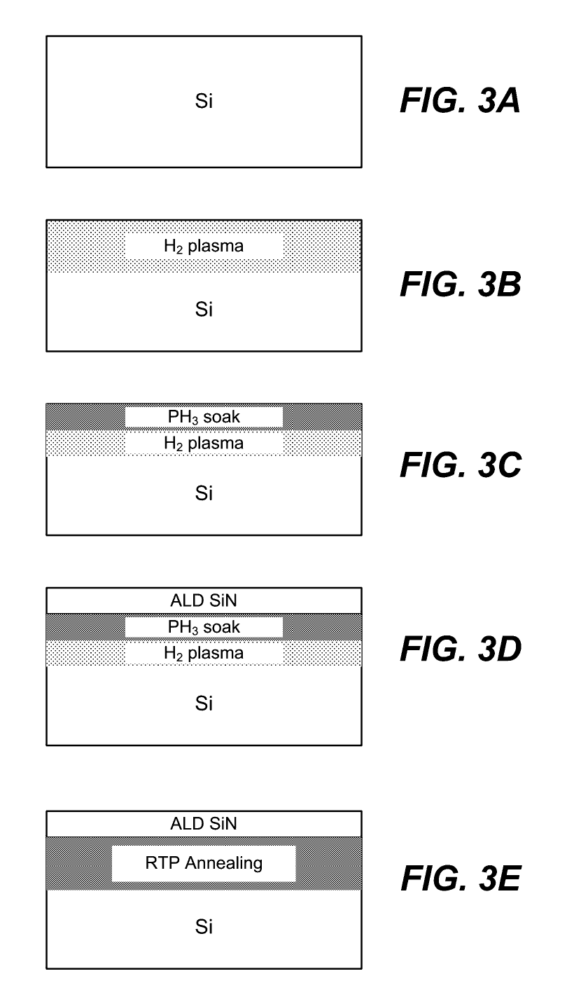

Referring to FIG. 1, a process flow for gas phase conformal doping of a semiconductor substrate in accordance with an aspect of this disclosure is provided. Reference is also made to FIGS. 3A-E which illustrate a process flow for gas phase conformal doping of a semiconductor substrate in accordance with one embodiment of this disclosure. FIG. 1 depicts operation 102, whereby a substrate is provided to a chamber, such as a process chamber within a tool suitable for processing substrates such as semiconductor substrates. The chamber may be a chamber in a multi-chamber apparatus or a single-chamber apparatus.

The substrate may be a silicon wafer, such as shown in part in FIG. 3A, e.g., a 200-mm wafer, a 300-mm wafer, or a 450-mm wafer, including wafers having one or more layers of material, such as dielectric, conducting, or semiconducting material deposited thereon. In some embodiments, the substrate includes a blanket layer of silicon, such as amorphous silicon, or a blanket layer of germanium. The substrate may include a patterned mask layer previously deposited and patterned on the substrate. For example, a mask layer may be deposited and patterned on a substrate including a blanket amorphous silicon layer.

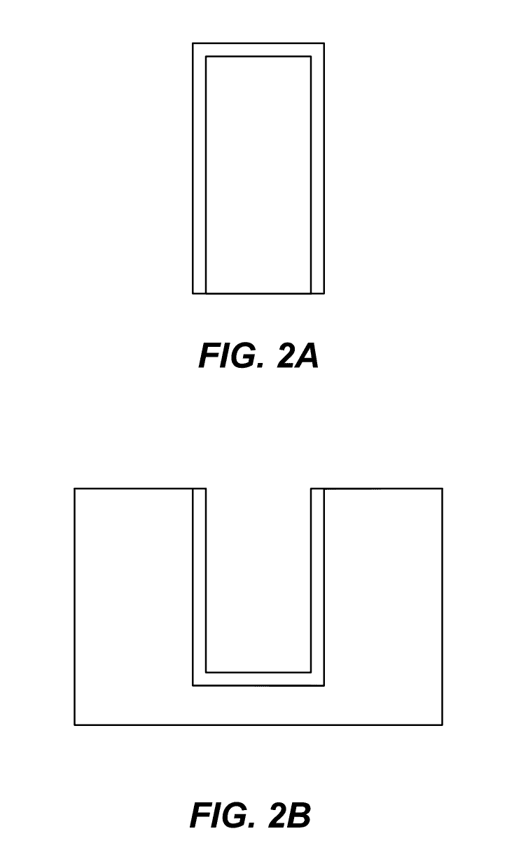

In some embodiments, the layers on the substrate may be patterned. Substrates may have “features” such as semiconductor blocks, vias or contact holes, which may be characterized by one or more surface structures or narrow and/or re-entrant openings, and high aspect ratios. The feature may be formed on or in one or more of the above described layers. One example of a feature is a crystalline semiconductor (e.g., silicon) “fin” on a substrate or layer, such as occurs in a 3D semiconductor structure, such as a FinFET or GAA device. For example, the distinguishing characteristic of a FinFET is that the conducting channel is wrapped by a thin silicon “fin” which forms the body of the device, such as is depicted in FIG. 2A. The thickness of the fin (measured in the direction from source to drain) determines the effective channel length of the device. Another example of a feature is a contact hole or via in a semiconductor substrate or a layer on the substrate, such as depicted in FIG. 2B.

In various embodiments, the feature may have an under-layer, such as a barrier layer or adhesion layer. Non-limiting examples of under-layers include dielectric layers and conducting layers, e.g., silicon oxides, silicon nitrides, silicon carbides, metal oxides, metal nitrides, metal carbides, and metal layers. In some embodiments, the surface of the substrate may include more than one type of material, such as if the substrate is patterned. The substrate includes at least one material to be etched and smoothened using disclosed embodiments. This material may be any of those described above—metals, dielectrics, semiconductor materials, and others. In various embodiments, these materials may be prepared for fabricating contacts, vias, gates, etc. The material to be processed in accordance with aspects of this disclosure is a crystalline semiconductor material, such as silicon, germanium, silicon-germanium. Silicon is commonly used.

In some embodiments, the substrate may undergo pre-processing to remove any residual oxides on the surface of the substrate materials prior to performing disclosed embodiments. For example, in some embodiments, substrates may be prepped by dipping the substrate into hydrogen fluoride (HF) prior to performing disclosed embodiments.

In operation 104, the substrate is exposed a hydrogen plasma (e.g., H₂ plasma) to modify a surface region crystal structure of the semiconductor substrate. In the description that follows, reference is made to a preferred embodiment of H₂ plasma as the hydrogen plasma. As noted above, it should be understood that other embodiments, using suitable hydrogen plasmas based on other hydrogen-containing species and mixtures, are also contemplated. The modification operation renders the semiconductor crystal structure in the surface region (FIG. 3B) more susceptible to embedding of dopant atoms in a subsequent gas phase doping exposure, but does not result in lattice or other mechanical damage, e.g., breakage of semiconductor-atom-to-semiconductor-atom (e.g., Si—Si) bonds, in the semiconductor crystal structure. The doping is conducted without energetic ion-induced implanting of the dopant into the substrate, and there is no deposition of a dopant species on the substrate surface. The substrate may be any crystalline semiconductor material, for example, silicon, germanium or silicon-germanium. Silicon is commonly used.

In various embodiments, the plasma may be an inductively coupled plasma or a capacitively coupled plasma. In some embodiments, an inductively coupled plasma may be set at a plasma power between about 10 W and about 3000 W (or microwave remote power) for about 5 sec to 120 seconds. In some embodiments, no bias is applied. The low temperature plasma exposure can be conducted at a temperature that is insufficient to reduce native oxide on the semiconductor surface, for example less than 500° C., or between about 300° C. and 500° C., such as about 360° C. Other relevant process parameters include gas flows about 50 to 500 sccm H₂, and 0 to 1000 sccm He as an inert carrier gas to facilitate control reaction time with partial pressure while avoiding any substrate surface damage that might occur with a larger inert molecule (e.g., Ar); and a process chamber pressure between about 1 and 1000 mT. Suitable conditions in a particular embodiment are 450 sccm H2, 500 sccm He, 5 mT chamber pressure, 1500 W (ICP), 360° C. chuck temperature, for 60 seconds.

In operation 106, the H₂ plasma-modified crystal structure of the semiconductor substrate is exposed to a dopant gas such that the modified crystal structure of the semiconductor substrate is doped (soaked) with the dopant (FIG. 3C). The dopant may be n-type (e.g., P, As Sb) or p-type (B), and may be supplied from any suitable gas (e.g., P from PH₃ gas, As from AsH₃ or B from B₂H₆ gas). The gas phase exposure can be conducted at a temperature of less than 100° C., or between about 20° C. and 100° C., such as about 45° C. or room temperature (e.g., about 20° C.) for between about 5 and 180 seconds. Other relevant process parameters include gas flow of about 50 to 1000 sccm dopant gas (e.g., PH₃, AsH₃, B₂H₆, etc.), 100 to 500 sccm H₂ as an inert carrier gas; and a process chamber pressure between about 1 and 1000 mT. Suitable conditions in a particular embodiment are 350 sccm PH₃, 500 sccm H₂, 80 mT chamber pressure, 1500 W (ICP), 45° C. chuck temperature, for 120 seconds.

In operation, 108, after the initial gas phase doping according to the most general aspect of the disclosure, the substrate may be capped with a thin (e.g., 2-20 nm) dielectric capping layer, typically an oxide or nitride layer, to prevent dopant from desorbing during subsequent processing or other damage to the doped surface region. An atomic layer deposited (ALD) silicon nitride (SiN) capping layer on a hydrogen plasma treated and gas phase doped silicon substrate is one specific embodiment (FIG. 3D). The capping deposition can be conducted at a temperature that is insufficient to cause substantial diffusion of the dopant in the substrate, for example less than 500° C., or between about 300° C. and 500° C., such as about 330-360° C. Other relevant process parameters include about 5 to 30 cycles of the following operations: a first step of purging with about 100 to 2000 sccm Ar at about 10 to 100 mT chamber pressure; a second step of SiH₄ soaking in about 5 to 20 sccm SiH₄(or SiH₂, SiCl₂H₂, etc.) and about 500 to 2000 sccm Ar at about 10 to 1000 mT chamber pressure; a third step of purging with about 100 to 1000 sccm N₂ and about 100 to 500 sccm Ar at a chamber pressure of about 10 to 200 mT; and a fourth step of nitridation in about 100 to 1000 sccm N₂ and about 10 to 200 sccm Ar, with about 100 to 1000 W ICP source power at about 5 to 100 mT chamber pressure. Suitable conditions in a particular embodiment are about 20 cycles of a first step of purging with about 1000Ar at about 60 mT chamber pressure; a second step of SiH₄ soaking in about 10 sccm SiH₄ and about 1000 sccm Ar at about 60 mT chamber pressure; a third step of purging with about 500 sccm N₂ and about 100 sccm Ar at a chamber pressure of about 10 mT; and a fourth step of nitridation in about 500 sccm N₂ and about 100 sccm Ar, with about 300 W ICP source power at about 10 mT chamber pressure; and a chuck temperature of about 350° C.

Alternatively, the capping layer may be deposited by ALD carbon or SiC.

In operation 110, after capping, the dopant at the semiconductor surface (semiconductor/cap interface) can be driven-in to the substrate by a thermal annealing treatment. The depth and concentration profile of the dopant may be controlled via this annealing operation. For a given amount of dopant initially embedded in the semiconductor substrate surface in the gas phase exposure operation, the depth and concentration profile of the dopant may be controlled by the duration and temperature of the thermal anneal. Examples of suitable annealing operations include heating at about 330-360° C. for about 1-10 minutes in N₂ atmosphere, for example at about 350° C. for about 3 minutes in N₂ atmosphere; or a rapid thermal anneal (RTP) at about 850 to 1050° C. for about 5 to 60 seconds in N₂ atmosphere, for example at about 950° C. for about 45 seconds in N₂ atmosphere (FIG. 3E).

Alternatively, the drive-in anneal may be conducted by laser annealing or flash lamp annealing, for example.

The depth of the dopant drive-in will also determine the depth of the junction. According to this disclosure, junction depths of from less than 5 nm up to 20 nm may be achieved with thermal annealing, with dopant concentration levels adequate to form transistor junctions, generally at least 5E18 atoms/cm³, or 1E19 atoms/cm³ and up to 1E20 atoms/cm³ or more at a depth of from about 2 to up to about 5 nm (e.g., 2, 3, 4, less than 5, or 5 nm), up to about 20 nm (e.g., 5, 10, 15 less than 20, or 20 nm) can be achieved by thermal annealing.

Such a doped region is suitable for and may be adapted to form part of an USJ. Moreover, doping in accordance with this disclosure may be conformal; that is, substantially all exposed semiconductor surfaces will have the same dopant concentration profile. So the disclosure is particularly applicable to the formation of USJs in three-dimensional (3D) semiconductor structures, such as fins and contacts, illustrated in FIGS. 2A and B, respectively, for FinFET, GAA and other devices.

Apparatus

Gas phase doping of hydrogen (e.g., H₂) plasma modified semiconductor substrates in accordance with this disclosure may be conducted in a suitable semiconductor processing tool. In this regard, inductively coupled plasma (ICP) reactors which may be suitable for H₂ plasma and gas phase dopant exposures, and capping and annealing of semiconductor substrates, including atomic layer deposition (ALD) and RTP operations, are now described. Although ICP reactors are described herein, in some embodiments, it should be understood that capacitively-coupled plasma (CCP) reactors or other appropriately-configured tools may also be used.

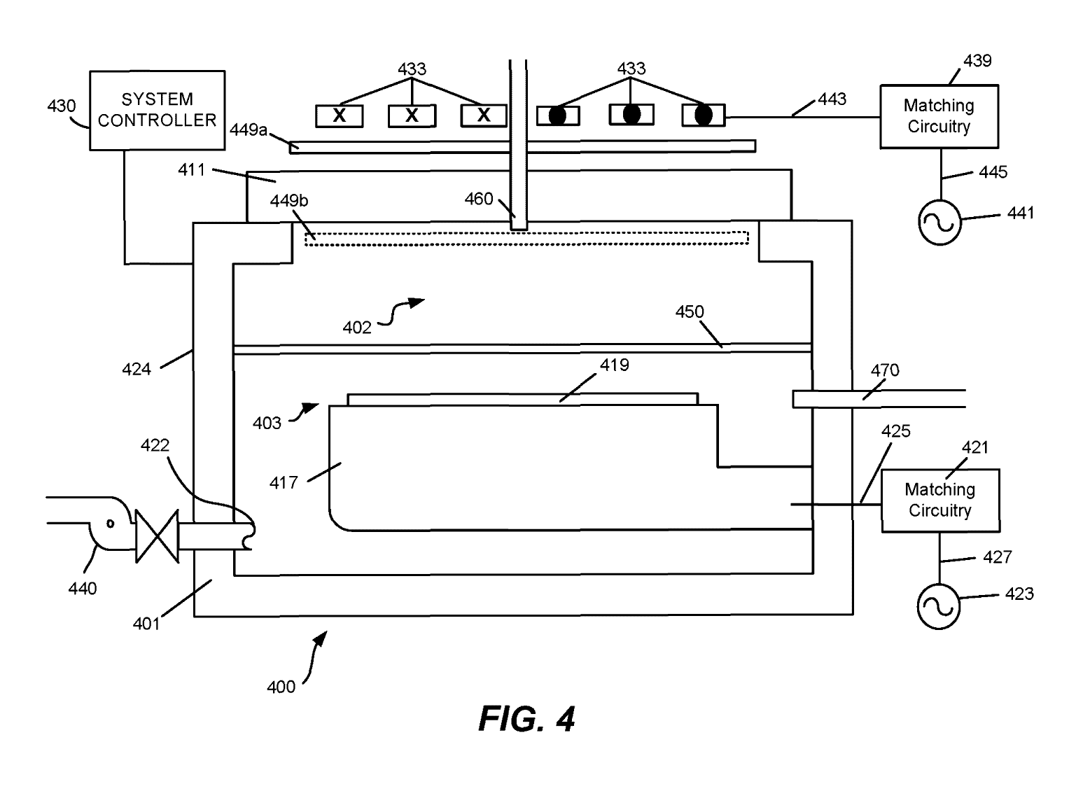

FIG. 4 schematically shows a cross-sectional view of an inductively coupled plasma integrated etching and deposition apparatus 400 appropriate for implementing certain embodiments herein, an example of which is a Kiyo® reactor, produced by Lam Research Corp. of Fremont, Calif. The inductively coupled plasma apparatus 400 includes an overall process chamber 424 structurally defined by chamber walls 401 and a window 411. The chamber walls 401 may be fabricated from stainless steel or aluminum. The window 411 may be fabricated from quartz or other dielectric material. An optional internal plasma grid 450 divides the overall process chamber into an upper sub-chamber 402 and a lower sub-chamber 403. In most embodiments, plasma grid 450 may be removed, thereby utilizing a chamber space made of sub-chambers 402 and 403.

A chuck 417 is positioned within the lower sub-chamber 403 near the bottom inner surface. The chuck 417 is configured to receive and hold a semiconductor wafer 419 upon which the etching and smoothening processes are performed. The chuck 417 can be an electrostatic chuck for supporting the wafer 419 when present. In some embodiments, an edge ring (not shown) surrounds chuck 417, and has an upper surface that is approximately planar with a top surface of the wafer 419, when present over chuck 417. The chuck 417 also includes electrostatic electrodes for chucking and dechucking the wafer 419. A filter and DC clamp power supply (not shown) may be provided for this purpose. Other control systems for lifting the wafer 419 off the chuck 417 can also be provided.

The chuck 417 can be electrically charged using an RF power supply 423. The RF power supply 423 is connected to matching circuitry 421 through a connection 427. The matching circuitry 421 is connected to the chuck 417 through a connection 425. In this manner, the RF power supply 423 is connected to the chuck 417. In various embodiments, a bias power of the electrostatic chuck may be set at less than about 100V_{b} or may be set at a different bias power depending on the process performed in accordance with disclosed embodiments. For example, the bias power may be between about 20 V_{b} and about 100 V_{b}, or at a bias power to reduce physical sputtering of a plasma species onto a wafer.

The chuck 417 disclosed herein may operate at elevated temperatures ranging between about 20 and 400° C. The temperature will depend on the process operation and specific recipe, for instance during the thermal annealing operation described above. About 350° C. is one example.

The wafer 19, when present, may also by subjected to RTP in the chamber during another implementation of the thermal annealing operation described above. RTP of a wafer may be accomplished, for example by halogen lamp RTP at about 950° C. in N₂ ambient for about 45 seconds.

Elements for plasma generation include a coil 433 is positioned above window 411. In some embodiments, a coil is not used in disclosed embodiments. The coil 433 is fabricated from an electrically conductive material and includes at least one complete turn. The example of a coil 433 shown in FIG. 4 includes three turns. The cross-sections of coil 433 are shown with symbols, and coils having an “X” extend rotationally into the page, while coils having a “” extend rotationally out of the page. Elements for plasma generation also include an RF power supply 441 configured to supply RF power to the coil 433. In general, the RF power supply 441 is connected to matching circuitry 439 through a connection 445. The matching circuitry 439 is connected to the coil 433 through a connection 443. In this manner, the RF power supply 441 is connected to the coil 433. An optional Faraday shield 449a is positioned between the coil 433 and the window 411. The Faraday shield 449a may be maintained in a spaced apart relationship relative to the coil 433. In some embodiments, the Faraday shield 449a is disposed immediately above the window 411. In some embodiments, the Faraday shield 449b is between the window 411 and the chuck 417. In some embodiments, the Faraday shield 449b is not maintained in a spaced apart relationship relative to the coil 433. For example, the Faraday shield 449b may be directly below the window 411 without a gap. The coil 433, the Faraday shield 449a, and the window 411 are each configured to be substantially parallel to one another.

Process and inert gases (e.g., hydrogen, dopant gases, capping layer precursors, etc.) may be flowed into the process chamber through one or more main gas flow inlets 460 positioned in the upper sub-chamber 402 and/or through one or more side gas flow inlets 470. Likewise, though not explicitly shown, similar gas flow inlets may be used to supply process gases to a capacitively coupled plasma processing chamber. A vacuum pump 440, e.g., a one or two stage mechanical dry pump and/or turbomolecular pump, may be used to draw process gases out of the process chamber 424 and to maintain a pressure within the process chamber 424. For example, the vacuum pump may be used to evacuate the lower sub-chamber 403 during a purge operation between stages of an ALD. A valve-controlled conduit may be used to fluidically connect the vacuum pump to the process chamber 424 so as to selectively control application of the vacuum environment provided by the vacuum pump. This may be done employing a closed-loop-controlled flow restriction device, such as a throttle valve (not shown) or a pendulum valve (not shown), during operational plasma processing. Likewise, a vacuum pump and valve controlled fluidic connection to the capacitively coupled plasma processing chamber may also be employed.

During operation of the apparatus 400, one or more process gases may be supplied through the gas flow inlets 460 and/or 470. In certain embodiments, process gases may be supplied only through the main gas flow inlet 460, or only through the side gas flow inlet 470. In some cases, the gas flow inlets shown in the figure may be replaced by more complex gas flow inlets, one or more showerheads, for example. The Faraday shield 449a and/or optional grid 450 may include internal channels and holes that allow delivery of process gases to the process chamber 424. Either or both of Faraday shield 449a and optional grid 450 may serve as a showerhead for delivery of process gases. In some embodiments, a liquid vaporization and delivery system may be situated upstream of the process chamber 424, such that once a liquid reactant or precursor is vaporized, the vaporized reactant or precursor is introduced into the process chamber 424 via a gas flow inlet 460 and/or 470.

Radio frequency power is supplied from the RF power supply 441 to the coil 433 to cause an RF current to flow through the coil 433. The RF current flowing through the coil 433 generates an electromagnetic field about the coil 433. The electromagnetic field generates an inductive current within the upper sub-chamber 402. The physical and chemical interactions of various generated ions and radicals with the wafer 419 can etch features of and selectively deposit layers on the wafer 419.

If the plasma grid 450 is used such that there is both an upper sub-chamber 402 and a lower sub-chamber 403, the inductive current acts on the gas present in the upper sub-chamber 402 to generate an electron-ion plasma in the upper sub-chamber 402. The optional internal plasma grid 450 limits the amount of hot electrons in the lower sub-chamber 403. In some embodiments, the apparatus 400 is designed and operated such that the plasma present in the lower sub-chamber 403 is an ion-ion plasma.

Both the upper electron-ion plasma and the lower ion-ion plasma may contain positive and negative ions, though the ion-ion plasma will have a greater ratio of negative ions to positive ions. Volatile etching and/or deposition byproducts may be removed from the lower sub-chamber 403 through port 422.

Apparatus 400 may be coupled to facilities (not shown) when installed in a clean room or a fabrication facility. Facilities include plumbing that provide processing gases, vacuum, temperature control, and environmental particle control. These facilities are coupled to apparatus 400, when installed in the target fabrication facility. Additionally, apparatus 400 may be coupled to a transfer chamber that allows robotics to transfer semiconductor wafers into and out of apparatus 400 using typical automation.

In some embodiments, a system controller 430 (which may include one or more physical or logical controllers) controls some or all of the operations of a process chamber 424. The system controller 430 may include one or more memory devices and one or more processors. In some embodiments, the apparatus 400 includes a switching system for controlling flow rates and durations when disclosed embodiments are performed. In some embodiments, the apparatus 400 may have a switching time of up to about 500 ms, or up to about 750 ms. Switching time may depend on the flow chemistry, recipe chosen, reactor architecture, and other factors.

In some implementations, the system controller 430 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be integrated into the system controller 430, which may control various components or subparts of the system or systems. The system controller, depending on the processing parameters and/or the type of system, may be programmed to control any of the processes disclosed herein, including the delivery of processing gases, bias power, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 430 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication or removal of one or more layers, materials, metals, oxides, silicon, silicon dioxide, surfaces, circuits, and/or dies of a wafer.

For example, a suitable controller 430 may have at least one processor and a memory communicatively connected with one another, the processor at least operatively connected with the plasma generation, temperature, flow-control and other semiconductor processing hardware, and the memory stores computer-executable instructions for controlling the processor to at least expose a semiconductor substrate to a hydrogen plasma to modify a surface region crystal structure of the semiconductor substrate without lattice or other mechanical damage in the semiconductor substrate crystal structure, and expose the hydrogen plasma-treated substrate surface to a dopant gas such that the modified surface region is doped with the dopant. The instructions may further include controls for other aspects of the methods described herein, including, for example, that the dopant is embedded in the crystal structure of the semiconductor substrate without energetic ion-induced implanting of the dopant into the substrate, depositing a capping dielectric layer on the gas phase-doped substrate surface, and thermally annealing the substrate to drive-in the gas phase-applied dopant.

The system controller 430, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 430 receives instructions in the form of data, which specify parameters for each of the processing steps to be performed during one or more operations. It should be understood that the parameters may be specific to the type of process to be performed and the type of tool that the controller is configured to interface with or control. Thus as described above, the system controller 430 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a hydrogen plasma (e.g., H₂ plasma) exposure chamber or module, a dopant exposure chamber or module, a deposition (e.g., ALD) chamber or module, a thermal anneal/RTP chamber or module, a clean chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

An ICP etch reactor (e.g., the Lam Research Kiyo®) has been described. As noted above, the techniques of this disclosure could also be practiced using an appropriately configured capacitively-coupled plasma (CCP) reactor (e.g., Lam Research Vector®) or strip tool (e.g., Lam Research Gamma), as will be apparent to those skilled in the art given this disclosure.

### EXPERIMENTAL

### Experiment 1

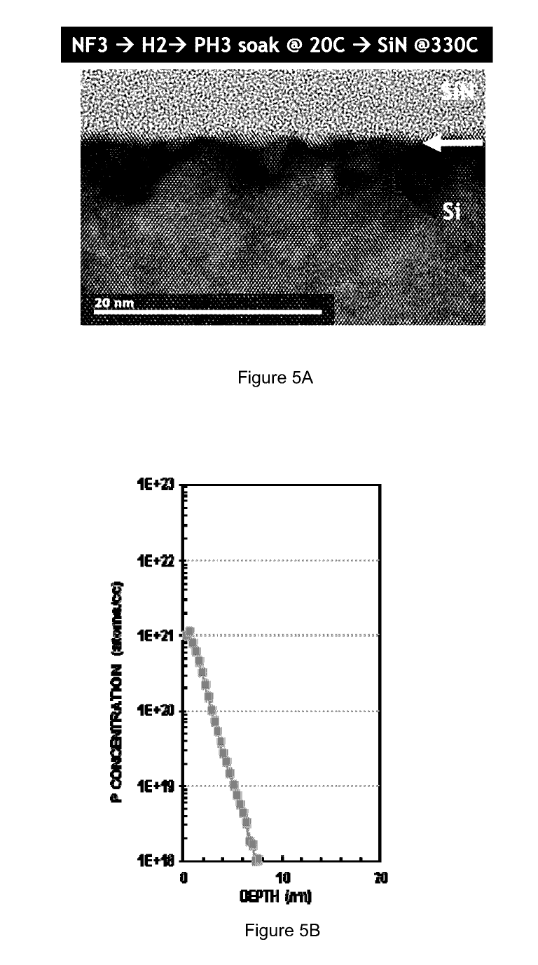

A silicon substrate was cleaned of any residual oxide by exposure to a fluorine-based etchant, exposed to a H₂ plasma of 450 sccm H2, 500 sccm He, 5 mT chamber pressure, 1500 W (ICP), 360° C. chuck temperature, for 60 seconds; then exposed to phosphine (PH₃) gas: 350 sccm PH₃, 500 sccm H₂, at 80 mT chamber pressure, 1500 W (ICP), 20° C. chuck temperature, for 120 seconds; followed by capping by PECVD SiN at 350° C. with 100 sccm Ar+1000 sccm N₂+30 sccm SiH₄, at 50 mT chamber pressure, 500 W ICP source power for 30 seconds. The results are illustrated in FIG. 5A, and an analysis of the dopant concentration profile is plotted in FIG. 5B.

As shown in FIG. 5A, the silicon substrate has a doped region, represented by the darker shading, extending about 5 to 7 nm into the bulk Si below the SiN capping layer. As shown in FIG. 5B, the dopant concentration is at least 5E18 atoms/cm³ up to 5nm into the Si, indicating a level of doping sufficient to form a USJ in this region.

### Experiment 2

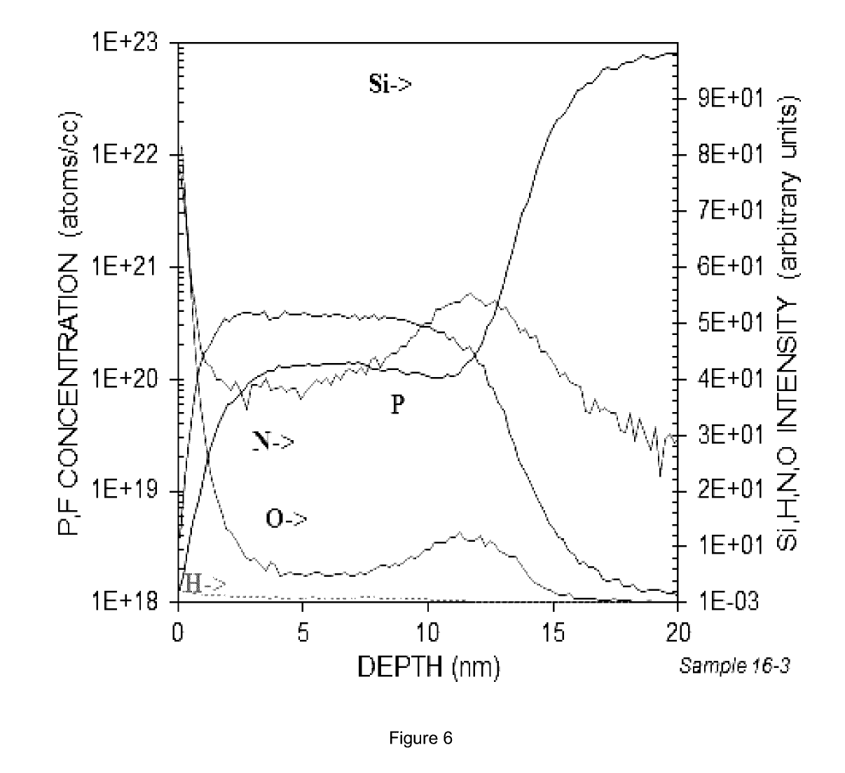

A silicon substrate was cleaned of any residual oxide by exposure to a fluorine-based etchant, exposed to a H₂ plasma of 450 sccm H2, 500 sccm He, 5 mT chamber pressure, 1500 W (ICP), 360° C. chuck temperature, for 60 seconds; then exposed to phosphine (PH₃) gas: 350 sccm PH₃, 350 sccm H₂, 200 sccm He, at 80 mT chamber pressure, 1500 W (ICP), 45° C. chuck temperature, for 120 seconds; followed by capping by ALD SiN at 360° C.: 20 cycles of a first step of purging with 1000Ar at 60 mT chamber pressure; a second step of SiH₄ soaking in 10 sccm SiH₄ and 1000 sccm Ar at 60 mT chamber pressure; a third step of purging with 500 sccm N₂ and 100 sccm Ar at a chamber pressure of about 10 mT; and a fourth step of nitridation in 500 sccm N₂ and 100 sccm Ar, with 300 W ICP source power at about 10 mT chamber pressure. After the capping, the RTP annealing of the substrate was conducted to drive-in the P dopant at 950° C. for 45 seconds in N₂ atmosphere. An elemental analysis of the substrate following RTP annealing showing the dopant concentration profile is plotted in FIG. 6.

The plot shows that the H and O levels are low to a depth of 20 nm into the sample. At about 10 nm depth, the N concentration begins dropping to near zero towards the 20 nm depth, while the Si concentration moves very high. This indicates the interface between the SiN cap and the bulk Si. The P concentration remains in the 1E21 atoms/cm³ to 1E19 atoms/cm³ range in through the first about 10 nm of depth of the bulk Si, indicating a level of doping sufficient to form a USJ in this region.

### CONCLUSION

A semiconductor processing method involving exposing a semiconductor substrate to a hydrogen plasma (e.g., H₂ plasma) to modify a surface region crystal structure of the substrate without lattice or other mechanical damage in the semiconductor substrate crystal structure, and then exposing the hydrogen plasma-treated substrate surface to a dopant gas such that the modified surface region is doped with the dopant can be used in the formation of USJs in three-dimensional (3D) semiconductor structures, such as FinFET and GAA devices. The doping is conducted without energetic ion-induced implanting of the dopant into the substrate, and results in doping with conformality, depth and dopant concentration profile not previously attainable.

It is understood that the examples and embodiments described herein are for illustrative purposes only and that various modifications or changes in light thereof will be suggested to persons skilled in the art. Although various details have been omitted for clarity's sake, various design alternatives may be implemented. Therefore, the present examples are to be considered as illustrative and not restrictive, and the disclosure is not to be limited to the details given herein, but may be modified within the scope of the appended claims.

1. A semiconductor processing method, comprising:
exposing a semiconductor substrate to a hydrogen plasma to modify a surface region crystal structure of the semiconductor substrate without lattice or other mechanical damage in the semiconductor substrate crystal structure; and
exposing the hydrogen plasma-modified crystal structure of the semiconductor substrate to a dopant gas such that the modified crystal structure of the semiconductor substrate is doped with the dopant.

2. The method of claim 1, wherein the dopant is embedded in the crystal structure of the semiconductor substrate without energetic ion-induced implanting of the dopant into the substrate.

3. The method of claim 2, further comprising depositing a capping dielectric layer on the gas phase-doped substrate surface.

4. The method of claim 3, further comprising thermally annealing the substrate to drive-in the gas phase-applied dopant.

5. The method of claim 4, wherein the hydrogen plasma exposure is a H₂ plasma conducted at a temperature below 500° C. insufficient to remove native oxide from the semiconductor surface.

6. The method of claim 5, wherein the gas phase doping is conducted at a temperature below 50° C.

7. The method of claim 6, wherein the capping is in situ SiN capping performed at a temperature of about 330 to 360° C.

8. The method of claim 7, wherein the annealing is conducted by heating the substrate to a temperature of about 350° C. for about 3 minutes in N2 atmosphere.

9. The method of claim 7, wherein the annealing is conducted by RTP at a temperature of about 950° C. for about 60 seconds.

10. The method of claim 1, wherein the substrate is a three-dimensional feature.

11. The method of claim 10, wherein the substrate is a contact hole.

12. The method of claim 10, wherein the substrate is a fin.

13. The method of claim 12, wherein the doped fin forms an ultrashallow junction (USJ) in a FinFET device.

14. The method of claim 12, wherein the USJ has a dopant concentration of at least 5E18 atoms/cm³ at a depth of from about 2 to up to about 5 nm.

15. The method of claim 12, wherein the USJ has a dopant concentration of at least 5E18 atoms/cm³ at a depth of up to 20 nm.

16. The method of claim 4, wherein the doping is conformal.

17. The method of claim 16, wherein the dopant is P sourced from PH₃ gas.

18. An ultrashallow junction (USJ), comprising:
a doped semiconductor having a crystalline surface region with a conformal dopant concentration of at least 5E18 atoms/cm³ at a depth of from about 2 to up to about 5 nm.

19. A semiconductor processing apparatus, the apparatus comprising:
(a) one or more process chambers, each process chamber comprising a chuck;
(b) one or more gas inlets into the process chambers and associated flow-control hardware; and
(c) a controller having at least one processor and a memory, wherein
the at least one processor and the memory are communicatively connected with one another,
the at least one processor is at least operatively connected with the flow-control hardware, and
the memory stores computer-executable instructions for controlling the at least one processor to at least:
(i) expose a semiconductor substrate to a hydrogen plasma to modify a surface region crystal structure of the semiconductor substrate without lattice or other mechanical damage in the semiconductor substrate crystal structure; and
(ii) and expose the hydrogen plasma-modified substrate surface to a dopant gas such that the modified surface region is doped with the dopant.

20. The apparatus of claim 19, wherein computer-executable instructions for controlling the at least one processor further comprise,
that the dopant is embedded in the crystal structure of the semiconductor substrate without energetic ion-induced implanting of the dopant into the substrate,
depositing a capping dielectric layer on the gas phase-doped substrate surface, and
thermally annealing the substrate to drive-in the gas phase-applied dopant.
